(19) United States
(12) Patent Application Publication
(10) Pub. No.: US 2009/0061584 A1
(43) Pub. Date: Mar. 5, 2009

(54) Semiconductor Process for Trench Power MOSFET

(76) Inventors: Wei-Chieh Lin, Hsinchu City (TW); Jen-Hao Yeh, Kaohsiung County (TW); Ming-Jang Lin, Hsinchu City (TW); Hsin-Yen Chiu, Taichung County (TW)

Correspondence Address: NORTH AMERICA INTELLECTUAL PROPERTY CORPORATION, P.O. BOX 506, MERRIFIELD, VA, 22116, US

(21) Appl. No.: 12/030,194

(22) Filed: Feb. 12, 2008

Related U.S. Application Data
(60) Provisional application No. 60/968,077, filed on Aug. 27, 2007.

(51) Int. Cl. H01L 21/336

(52) U.S. Cl. 438/270; 257/E21.419

(57) ABSTRACT

The present invention provides a semiconductor process for a trench power MOSFET. The semiconductor process includes providing a substrate, forming an EPI wafer on the surface, performing trench dry etching, performing HTP hard mask oxide deposition and channel self- align implant, performing boron (B) implant and completing the P-body region through a thermal process, performing arsenic (As) implant and completing the n+ source region through a thermal process, and depositing BPSG ILD, front side metal Al, and backside metal Ti/Ni/Ag.

### CROSS REFERENCE TO RELATED APPLICATIONS

This application claims the benefit of U.S. Provisional Application No. 60/968,077, filed on Aug. 27, 2007 and entitled “Channel Self-Align Trench Power MOSFET”, the contents of which are incorporated herein by reference.

### BACKGROUND OF THE INVENTION

1. Field of the Invention

The present invention is related to a semiconductor process for a trench power MOSFET. More particularly, this is a semiconductor process for reducing Cgd (gate-to-drain capacitance) and Qgd (gate-to-drain charge) in the gate to drain region of the trench power MOSFET.

2. Description of the Prior Art

The trench power MOSFET is a class structure semiconductor device in power manager application, which is used in many applications such as SMPS (Switched Mode Power Supplies), computer V-core or peripherals, backlight inverter, automotive, and motor control. Generally speaking, the trench power MOSFET needs smaller Cgd and Qgd. In the trench power MOSFET, Cgd is positive correlated to Qgd. When Cgd becomes larger, Qgd relatively becomes larger. And Qgd affects the switching velocity of the gate. When Qgd becomes larger, the switching velocity of the gate becomes slower. When Qgd becomes smaller, the switching velocity of the gate becomes faster. Actually, in switching velocity, faster is better.

In order to have faster switching velocity, all proprietors try their best to reduce Cgd and Qgd of the trench power MOSFET. A common method disclosed in American patent U.S. Pat. No. 6,084,264 is reducing Cgd of the gate by a thicker bottom oxide. Another method disclosed in American patent U.S. Pat. No. 6,291,298 is adding material with a different dielectric constant for reducing Cgd of the gate. Otherwise, the methods disclosed in American patents U.S. Pat. No. 6,979,621 and U.S. Pat. No. 5,80,1417 are utilizing deep trench, which is similar to a floating gate for reducing Cgd. However, the above processes for reducing Cgd all have higher cost and have higher complexity. Therefore the depth of the trench is not easy to control and generates unstable results.

### SUMMARY OF THE INVENTION

It is therefore a primary objective of the claimed invention to provide a semiconductor process for reducing Cgd and Qgd in the gate to drain region of the trench power MOSFET. More particularly, the self-align method is utilized in the gate to reduce the exposure area of the gate for reducing the equivalent capacitance in the gate to drain region.

The present invention discloses a semiconductor process for reducing Cgd and Qgd in the gate to drain region of the trench power MOSFET, which comprises providing a substrate, forming an EPI wafer on the surface of the substrate, performing trench dry etching by reactive ion etch (RIE), performing HTP hard mask oxide deposition and doing channel self-align implant on the surface of the EPI wafer for forming a self-align channel, performing boron (B) implant and forming the P-body region through a thermal process, performing arsenic (As) implant and forming an n+ source region through a thermal process, and depositing BPSG ILD, front side metal Al and backside metal Ti/Ni/Ag.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a side view diagram of an EPI wafer.

FIG. 2 illustrates a schematic diagram of trench dry etching by RIE.

FIG. 3 illustrates a schematic diagram of channel self-align implant.

FIG. 4 illustrates a schematic diagram of gate oxide process.

FIG. 5 illustrates a schematic diagram of n+ implant.

FIG. 6 illustrates a schematic diagram of a trench power MOSFET.

FIG. 7 illustrates a comparative diagram between the present invention and the traditional trench power MOSFET.

FIG. 8 illustrates a comparative diagram between the present invention and the traditional trench power MOSFET.

FIG. 9 illustrates a schematic diagram of a semiconductor process according to an embodiment of the present invention.

### DETAILED DESCRIPTION

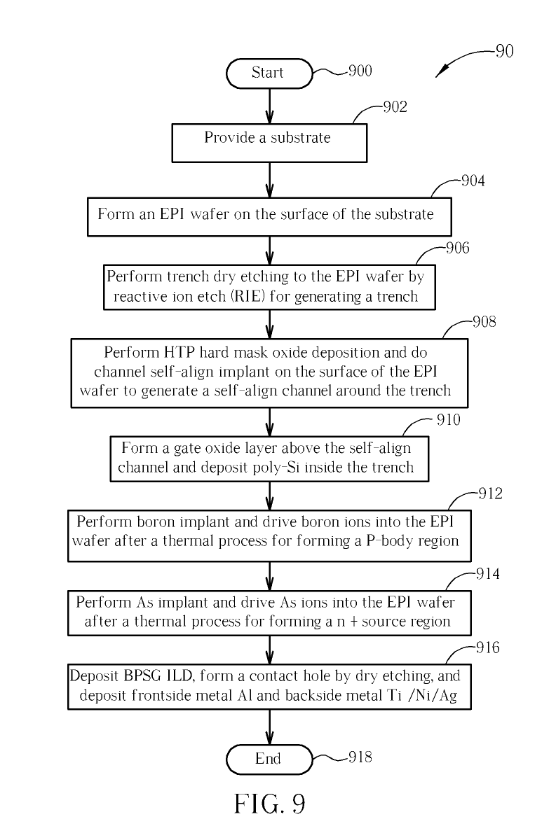

Please refer to FIG. 9. FIG. 9 illustrates a schematic diagram of a semiconductor process 90 according to an embodiment of the present invention. The semiconductor process 90 is utilized for reducing Cgd and Qgd in the gate to drain region of a trench power MOSFET, which is used in many applications such as SMPS (Switched Mode Power Supplies), computer V-core or peripherals, backlight inverter, automotive, and motor control. The semiconductor process 90 comprises following steps:

Step 900: Start.

Step 902: Provide a substrate.

Step 904: Form an EPI wafer on the surface of the substrate.

Step 906: Perform trench dry etching to the EPI wafer by reactive ion etch (RIE) for generating a trench.

Step 908: Perform HTP hard mask oxide deposition and do channel self-align implant on the surface of the EPI wafer to generate a self-align channel around the trench.

Step 910: Form a gate oxide layer above the self-align channel and deposit poly-Si inside the trench.

Step 912: Perform boron implant and drive boron ions into the EPI wafer after a thermal process for forming a P-body region.

Step 914: Perform As implant and drive As ions into the EPI wafer after a thermal process for forming a n+ source region.

Step 916: Deposit BPSG ILD, form a contact hole by dry etching, and deposit frontside metal Al and backside metal Ti/Ni/Ag.

Step 918: End.

According to the semiconductor process 90, the embodiment of the present invention is performing trench dry etching by RIE for generating a trench and forming a self-align channel around the trench through HTP hard mask oxide deposition and channel self-align implant. Then the embodiment of the present invention forms a gate oxide layer and deposits poly-Si inside the trench, drives boron ions into the EPI wafer through a thermal process for forming a P-body region, and drives As ions into the EPI wafer through a thermal process for forming an n+ source region. Finally, the embodiment of the present invention deposits BPSG ILD, forms a contact hole by dry etching, and deposits frontside and backside metal. Then, the semiconductor process 90 can effectively reduce Cgd and Qgd in the gate to drain region of the trench power MOSFET by the self-align channel.

Note that, the substrate is superiorly an n+ substrate and the EPI wafer is superiorly an n− EPI wafer. Otherwise, the surface of the EPI wafer is covered with a hard mask by photo resister with photo exposure and developing process before performing trench dry etching. The HTP hard mask oxide is deposited at the bottom of the trench and removed by BOE wet etching after performing trench dry etching. The embodiment of the present invention is superiorly doing the channel self-align implant with wafer tilt of 7 degrees. The frontside metal is Al and the backside metal is Ti/Ni/Ag.

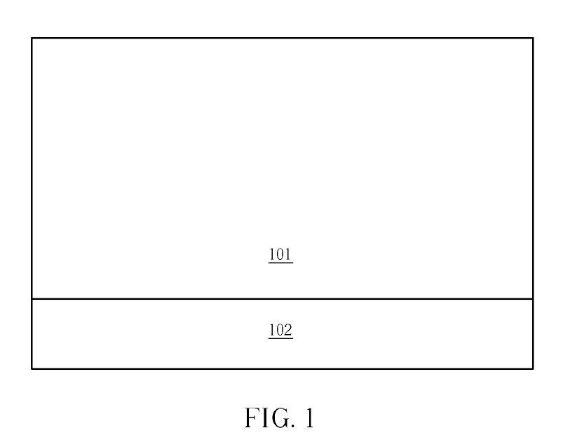

About the embodiment of the semiconductor process 90, please refer from FIG. 1 to FIG. 6. The schematic diagram of the trench power MOSFET through the semiconductor process 90 is illustrated from FIG. 1 to FIG. 6. In the FIG. 1, the semiconductor first provides an n+ substrate 102 and forms an n− EPI wafer 101 on the surface of the n+ substrate 102.

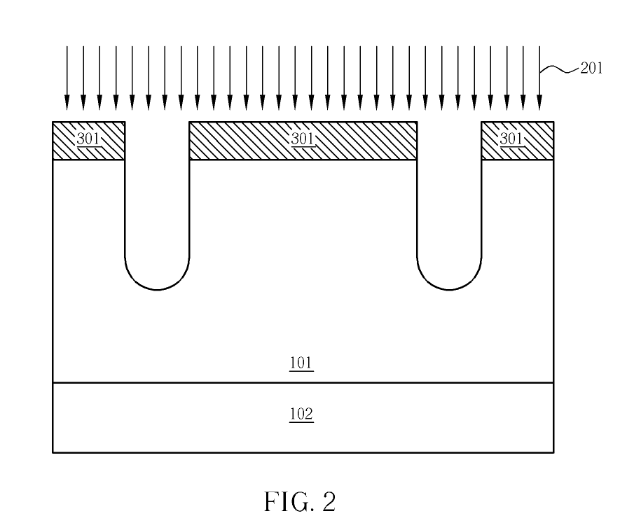

FIG. 2 illustrates a schematic diagram of the trench dry etching by RIE. In the FIG. 2, hard mask 301 is formed by photo resistor with a photo exposure and develop process and a trench dry etching 201 is following processed in the semiconductor process 90.

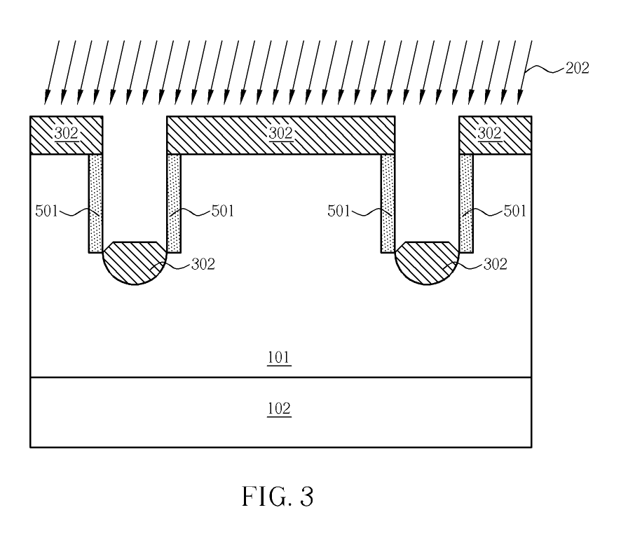

FIG. 3 illustrates a schematic diagram of channel self-align implant. As shown in FIG. 3, the semiconductor performs an HTP hard mask oxide deposition process on the surface of the n− EPI wafer 101 and does Channel Self-Align implant with a wafer tilt of 7 degrees for forming the self-align channel 501. Then the HTP hard mask oxide is removed by BOE wet etching for controlling the depth of the trench. In other words, the semiconductor process 90 is utilizing the BOE wet etching (anisotropic etching) to remove the HTP hard mask oxide 302. Compared to previous methods, the present invention does not use extra masks and the deposition oxide can be selectively removed.

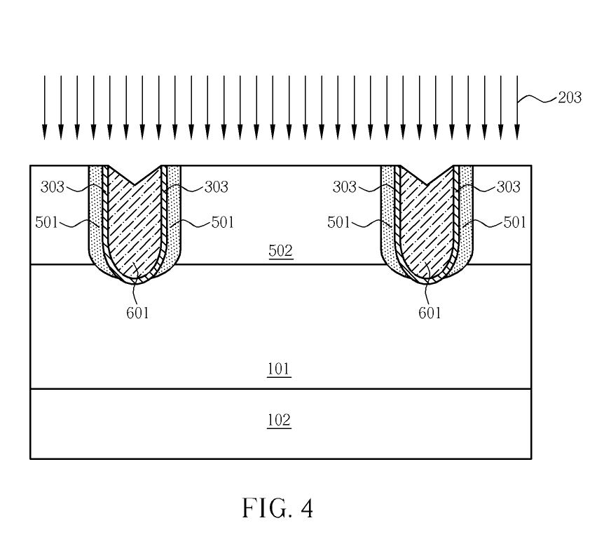

FIG. 4 illustrates a schematic diagram of the gate oxide process. In the FIG. 4, the gate oxide layer is the region 303. The semiconductor process 90 deposits poly-Si 601 into the trench, performs a boron implant 203, and drives the boron ions into the n− EPI wafer 101 through a thermal process for forming the P-body region 502.

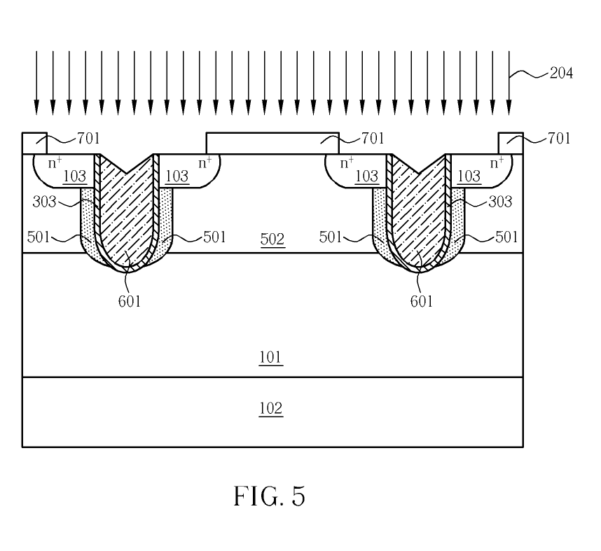

In the FIG. 5, the As source region 103 in the semiconductor process 90 is formed by an As implantation defined by photo resistor 701 and completed after a thermal process.

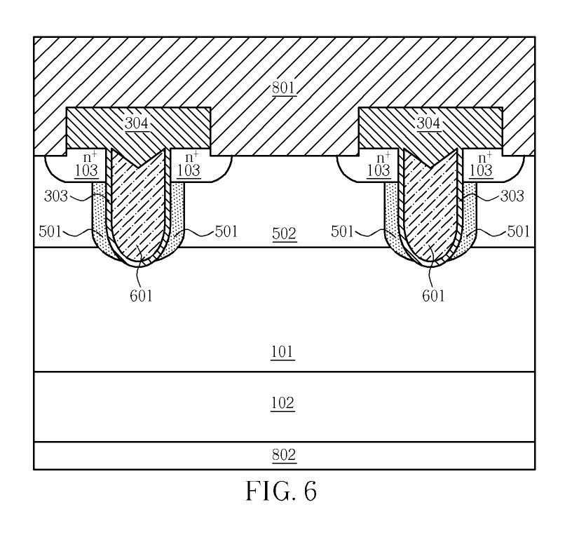

In the FIG. 6, the semiconductor 90 deposits the BPSG ILD 304 on the surface of the n− EPI wafer 101, deposits frontside metal Al 801 and backside metal Ti/Ni/Ag 802 after the contact hole fabrication by dry etching.

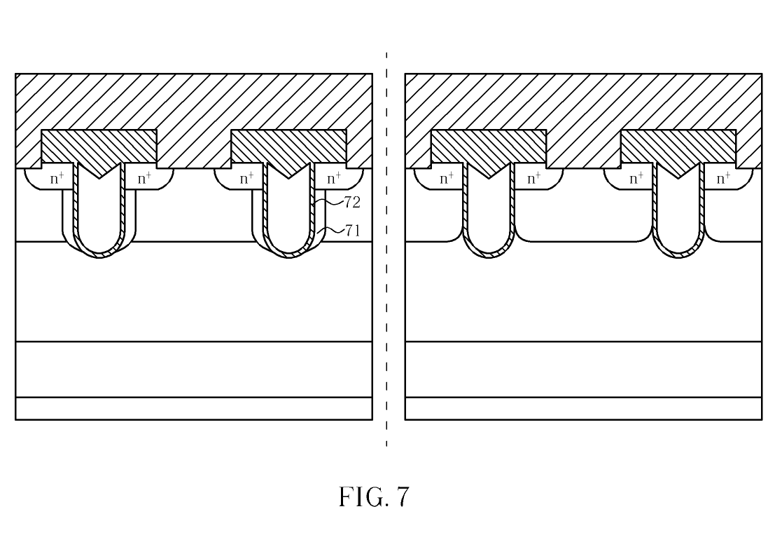

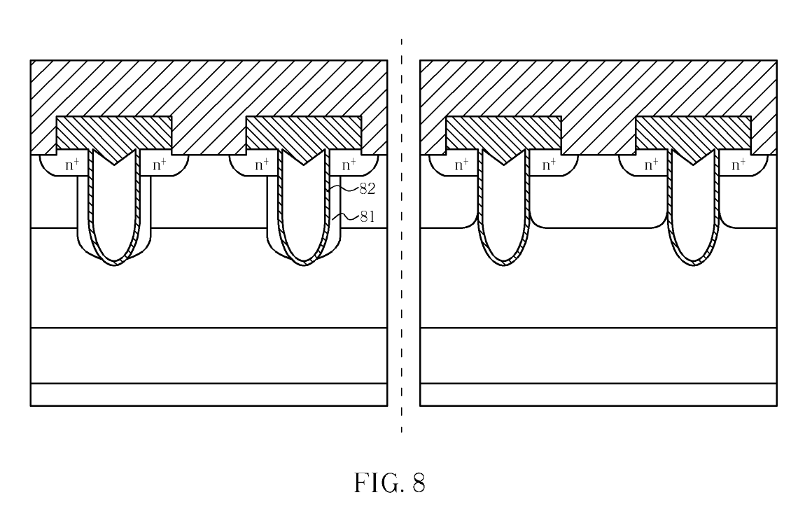

Note that, comparing to previous traditional processes, the process of the present invention is especially adding the self-align channel 501 surrounding around the gate oxide layer 303. Please refer to FIG. 7 and FIG. 8.

FIG. 7 illustrates a comparative diagram between the present invention and the traditional trench power MOSFET. The left side shown in FIG. 7 is the trench power MOSFET of the present invention. The right side shown in FIG. 7 is the traditional trench power MOSFET. Comparing the left one to the right one, the exposure area of the gate in the left one is smaller than the right one to generate smaller Cgd in the gate to drain region. FIG. 8 also illustrates a comparative diagram between the present invention and the traditional trench power MOSFET. The difference is the depth of the gate is deeper than the gate shown in FIG. 7. And the same effect is the exposure area of the gate 82 surrounded by the self-align channel 81 is also smaller than the traditional one and more obvious.

Therefore, after adding the self-align channel, the self-align channel can self-adjust along the depth of the gate for letting the exposure area of the gate become smaller. Additionally, Cgd in the gate to drain region also becomes smaller. In other words, when the depth of the gate becomes deeper, the self-align channel will extend downward along the gate for letting the exposure area of the gate become smaller. Cgd and Qgd in the gate to drain region also become smaller and cannot be affected by the depth of the gate.

In conclusion, the etching process of the trench power MOSFET provided by the present invention can self-adjust by the self-align channel changing with the depth of the gate for reducing Cgd and Qgd in the gate to drain region of the trench power MOSFET. Comparing to previous processes, the present invention has lower cost and complexity and is easily controlled for generating more stable results.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process for lowering Cgd and Qgd of a Trench Power MOSFET comprising:
providing a substrate;
forming an n-type EPI wafer on the substrate;
performing a trench dry etching process to the n-type EPI wafer utilizing a reactive ion etching process for generating a trench;
performing an HTP hard mask oxide deposition and doing Channel Self-Align implant for forming a self-aligning channel surrounding the trench;
forming a gate oxide layer on the surface of the trench and depositing poly-Si into the trench;
performing boron implantation for forming a P-body region on the side of the trench by driving the boron ions inside the EPI wafer through a thermal process;
performing n+ implantation for forming the n+ source region by driving the n+ inside the EPI wafer through a thermal process; and
depositing BPSG ILD and forming a contact hole through a dry etching process, then depositing front side and backside metal.

2. The semiconductor process of the claim 1, wherein the surface of the EPI wafer is covered with a hard mask before performing the trench dry etching process.

3. The semiconductor process of the claim 2, wherein the hard mask is generated by photoresist with a photo exposure and development process.

4. The semiconductor process of claim 1, wherein doing Channel Self-Align implant is doing Channel Self-Align implantation to the surface of the EPI wafer with a 7-degree tilt.

5. The semiconductor process of claim 1, wherein the depth of the self-aligning channel corresponds to the depth of the gate.

6. The semiconductor process of claim 1, wherein the HTP hard mask oxide formed by the HTP hard mask oxide deposition process is removed by a BOE wet etching process.

7. The semiconductor process of claim 1, wherein the material of the front side metal is Al.

8. The semiconductor process of claim 1, wherein the material of the backside metal is Ti/Ni/Ag.
